(19) United States
(12) Patent Application Publication
(10) Pub. No.: US 2019/0157625 A1
(43) Pub. Date: May 23, 2019

(54) PRODUCTION METHOD FOR EL DEVICE

(71) Applicant: Sharp Kabushiki Kaisha, Sakai City, Osaka (JP)

(72) Inventor: Masaki NAKAYAMA, Sakai City (JP)

(21) Appl. No.: 15/761,824

(22) PCT Filed: Feb. 28, 2017
(86) PCT No.: PCT/JP2017/007893

§ 371 Date: Mar. 21, 2018

(51) Int. Cl. H01L 51/56; H01L 51/52; H01L 27/32; H01L 51/00

(52) U.S. Cl. CPC H01L 51/56; H01L 51/5253; H01L 27/3258; H01L 2227/326; H01L 51/0097; H01L 2227/323; H01L 51/003

(57) ABSTRACT

The disclosure provides a production method for an EL device including a base layer, a light-emitting element layer, a plurality of terminals, and an electronic circuit board mounted on the plurality of terminals; the production method including: a preparation step of directly or indirectly applying heat and pressure to a prescribed region including the plurality of terminals without any overlap between the plurality of terminals and the electronic circuit board; and a thermocompression bonding step of thermocompression-bonding the plurality of terminals and the electronic circuit board.

### TECHNICAL FIELD

The disclosure relates to an electroluminescence element (EL) device including an EL element.

### BACKGROUND ART

A configuration in which a flexible printed circuit board (FPC) is mounted on a device including an organic EL element is described in PLT 1.

### CITATION LIST

### Patent Literature

PLT 1: Japanese Republished Patent Application Publication “WO 2013-99135” (published on Jul. 4, 2013)

### SUMMARY

### Technical Problem

When mounting an electronic circuit board on a device including a light emitting element by thermocompression bonding, there is a risk that the wiring or the like in the device may be damaged or that there may be mounting defects due to the deformation of the portion supporting the mounting surface.

### Solution to Problem

The production method for an EL device according to one aspect of the disclosure is a production method for an EL device including a base layer, a light-emitting element layer, a plurality of terminals, and an electronic circuit board mounted on the plurality of terminals. The production method includes: performing a preparation step of directly or indirectly applying heat and pressure to a prescribed region including the plurality of terminals without any overlap between the plurality of terminals and the electronic circuit board; and then thermocompression-bonding the electronic circuit board to the plurality of terminals.

### Advantageous Effects of Disclosure

According to one aspect of the disclosure, the risk that the wiring or the like in the device may be damaged or that there may be mounting defects can be reduced.

### BRIEF DESCRIPTION OF DRAWINGS

FIG. 1 is a flowchart illustrating an example of the production method for an EL device.

FIG. 2A is a cross-sectional view illustrating an example of the configuration of the EL device of this embodiment during the formation of the EL device, and FIG. 2B is a cross-sectional view illustrating an example of the configuration of the EL device of this embodiment.

FIG. 3 is a flowchart illustrating the mounting step in a first embodiment.

FIGS. 4A to 4D are plan views illustrating the mounting step (IC chip) in the first embodiment.

FIGS. 5A to 5H are cross-sectional views illustrating the mounting step in the first embodiment.

FIGS. 6A to 6C are a plan view and cross-sectional views illustrating the configuration of the EL device of the first embodiment.

FIG. 7 is a block diagram illustrating the configuration of an EL device production apparatus of another embodiment.

FIGS. 8A to 8D are plan views illustrating the mounting step (FPC) in the first embodiment.

FIG. 9 is a flowchart illustrating the mounting step in a second embodiment.

FIGS. 10A to 10D are plan views illustrating the preparation step in the second embodiment.

FIGS. 11A to 11F are cross-sectional views illustrating the preparation step in the second embodiment.

### DESCRIPTION OF EMBODIMENTS

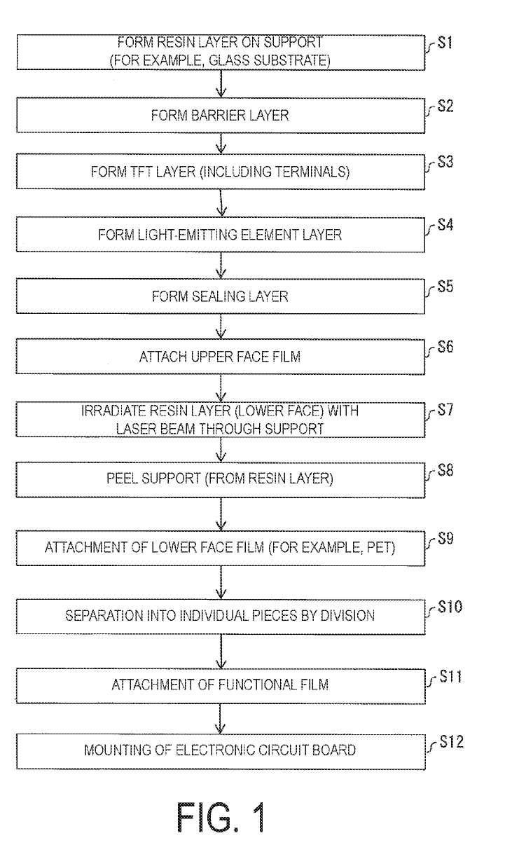

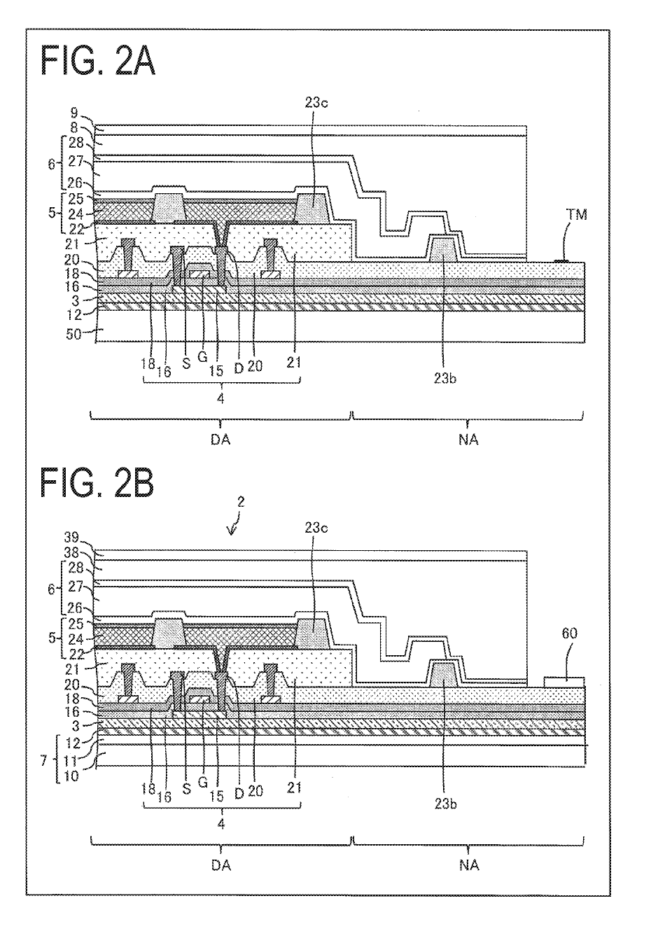

FIG. 1 is a flowchart illustrating an example of the production method for an EL device. FIG. 2A is a cross-sectional view illustrating an example of the configuration of the EL device of a first embodiment during the formation of the EL device. FIG. 2B is a cross-sectional view illustrating an example of the configuration of the EL device of the first embodiment.

As illustrated in FIGS. 1 and 2A, a resin layer 12 is first formed on a transparent support 50 (for example, a glass substrate) (step S1). Next, a barrier layer 3 is formed (step S2). Next, a TFT layer 4 including inorganic insulating films 16, 18, and 20 and an organic interlayer film 21 is formed (step S3). Next, a light-emitting element layer (for example, an OLED element layer) 5 is formed (step S4). Next, a sealing layer 6 including a first inorganic sealing film 26, a second inorganic sealing film 28, and an organic sealing film 27 is formed (step S5). Next, an upper face film 9 is attached to the sealing layer 6 via an adhesive layer 8 (step S6).

Next, the lower face of the resin layer 12 is irradiated with a laser beam through the glass substrate 50 (step S7). Here, the resin layer 12 absorbs the laser beam which is irradiated onto the lower face of the glass substrate 50 and passes through the glass substrate 50. As a result, the lower face of the resin layer 12 (interface with the glass substrate 50) is altered by abrasion, and the bonding strength between the resin layer 12 and the glass substrate 50 decreases. Next, the glass substrate 50 is peeled from the resin layer 12 (step S8). Next, a lower face film 10 (for example, PET) is attached to the lower face of the resin layer 12 via an adhesive layer 11 (step S9). Next, the layered body with the lower face film is divided to form individual pieces (step S10). Next, a functional film 39 is attached via an adhesive layer 38 (step S11). Next, an electronic circuit board 60 is mounted on the end portion of the TFT layer 4 to obtain the EL device 2 formed into an individual piece as illustrated in FIG. 2B (step S12). Note that each step is performed by a production apparatus for an EL device.

The base layer 7 is flexible and includes the resin layer 12, the adhesive layer 11, and the lower face film 10. Examples of the material of the resin layer 12 include polyimides, epoxies, and polyamides. Examples of the material of the lower face film 10 include polyethylene terephthalate (PET).

The barrier layer 3 is a layer configured to prevent water or impurities from reaching the TFT layer 4 or the light-emitting element layer 5. The barrier layer 3 may be composed of a silicon oxide film, silicon nitride film, or silicon oxinitride film formed by CVD, or a layered film thereof, for example. The thickness of the barrier layer 3 is, for example, from 50 nm to 1500 nm.

The TFT layer 4 includes a semiconductor film 15, an inorganic insulating film 16 (gate insulating film) formed on the upper side of the semiconductor film 15, a gate electrode G formed on the upper side of the gate insulating film 16, inorganic insulating films 18 and 20 formed on the upper side of the gate electrode G, a source electrode S, drain electrode D, and terminal TM formed on the upper side of the inorganic insulating film 20, and an organic interlayer film 21 formed on the upper side of the source electrode S and the drain electrode D. The semiconductor film 15, the inorganic insulating film 16, the gate electrode G, the inorganic insulating films 18 and 20, the source electrode S, and the drain electrode D constitute a thin film transistor (TFT). A plurality of terminals TM used for a connection with an electronic circuit board such as an IC chip or a flexible printed circuit (FPC) are formed on the end portion (non-display area NA) of the TFT 4.

The semiconductor film 15 is made of a low-temperature polysilicon (LTPS) or an oxide semiconductor, for example. The gate insulating film 16 may be composed of a silicon oxide (SiOx) film or silicon nitride (SiNx) film formed by a CVD method, or a layered film thereof, for example. The gate electrode G, the source electrode S, the drain electrode D, and the terminals are composed of a single-layer film or a layered film of a metal including at least one of the group consisting of aluminum (Al), tungsten (W), molybdenum (Mo), tantalum (Ta), chromium (Cr), titanium (Ti), and copper (Cu). Note that in FIGS. 2A and 2B, the TFT using the semiconductor film 15 as a channel is illustrated as a top-gate structure, but the TFT may also have a bottom-gate structure (for example, when the channel of the TFT is an oxide semiconductor).

The inorganic insulating films 18 and 20 may be composed of a silicon oxide (SiOx) film or silicon nitride (SiNx) film formed by a CVD method, or a layered film thereof, for example. The organic interlayer film 21 may be made of a coatable photosensitive organic material such as polyimide or an acrylic. An anode electrode 22 is photoreflective and is formed by the layering of Indium Tin Oxide (ITO) and an alloy containing Ag.

The light-emitting element layer 5 (for example, an OLED layer) includes an anode electrode 22 formed on the upper side of the organic interlayer film 21, a partition 23c configured to define subpixels of the display area DA, a bank 23b formed in the non-display area NA, an EL (electroluminescence) layer 24 formed on the upper side of the anode electrode 22, and a cathode electrode 25 formed on the upper side of the EL layer 24.

The partition 23c and the bank 23b may be formed in the same step, for example, using a coatable photosensitive organic material such as a polyimide, an epoxy, or an acrylic. The bank 23b of the non-display area NA is formed on the inorganic insulating film 20. The bank 23b defines the edge of the organic sealing film 27.

The EL layer 24 is formed by vapor deposition or an ink-jet method in a region (subpixel region) enclosed by the partition 23c. When the light-emitting element layer 5 is an organic light-emitting diode (OLED) layer, the EL layer 24 is formed by layering a hole injecting layer, a hole transport layer, a light emitting layer, an electron transport layer, and an electron injecting layer sequentially from the lower layer side, for example. The cathode electrode 25 may be made of a transparent metal such as Indium Tin Oxide (ITO) or Indium Zinc Oxide (IZO).

When the light-emitting element layer 5 is an OLED layer, the holes and electrons are recombined in the EL layer 24 by a drive current between the anode electrode 22 and the cathode electrode 25, and the resulting excitons fall into a ground state, which causes light to be discharged.

Note that the light-emitting element layer 5 is not limited to the OLED layer described above and may be an inorganic light-emitting diode layer or a quantum dot light-emitting diode layer.

The sealing layer 6 includes the first inorganic sealing film 26 configured to cover the partition 23c and the cathode electrode 25, the organic sealing film 27 configured to cover the first inorganic sealing film 26, and the second inorganic sealing film 28 configured to cover the organic sealing film 27.

The first inorganic sealing film 26 and the second inorganic sealing film 28 may each be composed of a silicon oxide film, silicon nitride film, or silicon oxinitride film formed by CVD, or a layered film thereof, for example. The organic sealing film 27 is a transparent organic insulating film which is thicker than the first inorganic sealing film 26 and the second inorganic sealing film 28 and may be made of a coatable photosensitive organic material such as a polyimide or an acrylic. For example, an ink containing such an organic material may be applied with an ink jet to the first inorganic sealing film 26 and then cured by UV irradiation. The sealing layer 6 covers the light-emitting element layer 5 and prevents the penetration of foreign matter such as water or oxygen into the light-emitting element layer 5.

Note that the upper face film 9 is attached to the sealing layer 6 via the adhesive layer 8 and functions as a supporting material when the glass substrate 50 is peeled. An example of the material of the upper face film 9 is polyethylene terephthalate (PET).

The lower face film 10 is a film for producing an EL device with excellent flexibility by attaching the lower face film 10 to the lower face of the resin film 12 after peeling the glass substrate 50. An example of the material thereof is PET.

The functional film 39 has an optical compensation function, a touch sensor function, and a protective function. The electronic circuit board 60 is an IC chip or a flexible printed circuit board mounted on a plurality of terminals, for example.

### First Embodiment

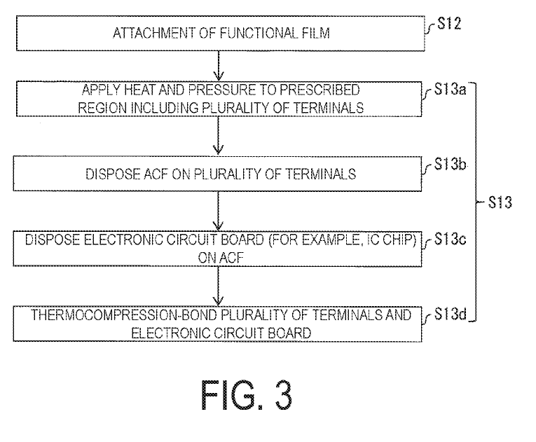

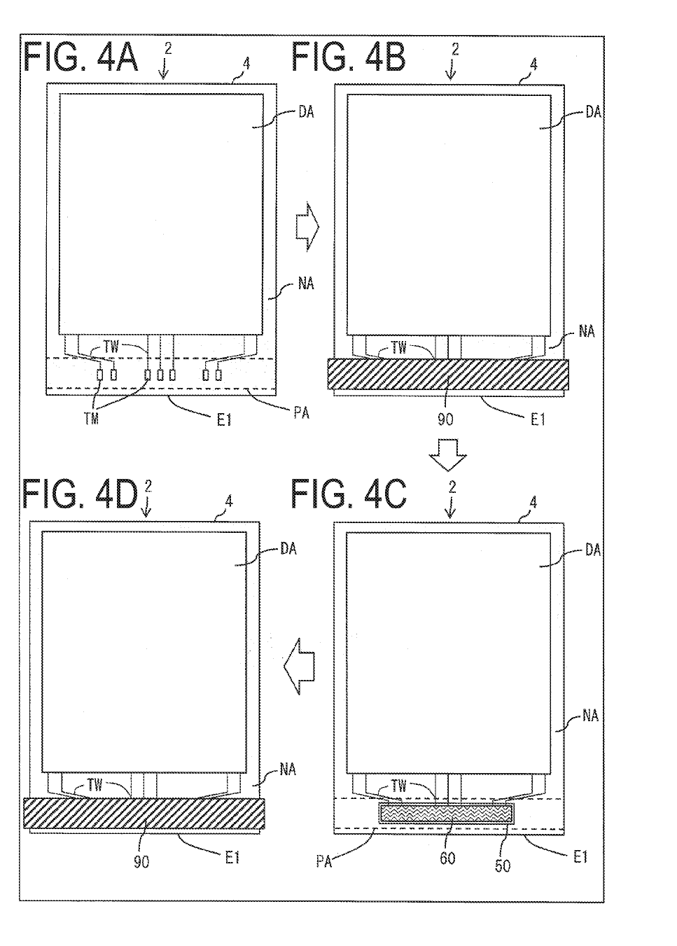

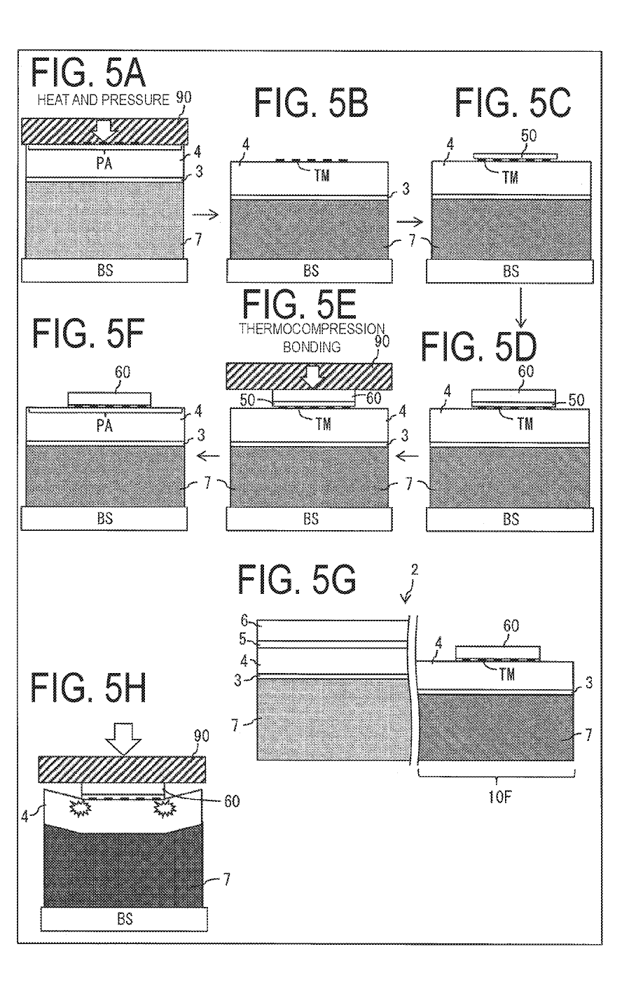

FIG. 3 is a flowchart illustrating the mounting step in a first embodiment. FIGS. 4A to 4D are plan views illustrating the mounting step in the first embodiment. FIGS. 5A to 5H are cross-sectional views illustrating the mounting step in the first embodiment.

First, as illustrated in FIGS. 3, 4A, 4B, and 5A, a layered body including a lower face film 10, a resin layer 12, a barrier layer 3, and a TFT layer 4 is placed on a support BS, and heat and pressure are applied to a prescribed region including a plurality of terminals TM using a head 90 of a thermocompression bonding tool (preparation step, step S13a).

The prescribed region (blank strike region) is a portion of the surface of the TFT layer 4 positioned in a non-display region NA and is a region along one of the edges of the TFT layer 4. The prescribed region PA is set so that, in a plan view, the mounting region of the electronic circuit board is contained within the edge. The support BS, which is in contact with and supports the lower face film 10, is made of a harder material than the material of the lower face film 10, for example, a metal material such as SUS.

The terminals TM are connected to various types of signal wiring or power supply wiring in the TFT layer via terminal wiring TW.

When step S13a is complete, the head 90 of the thermocompression bonding tool is separated from the plurality of terminals TM (FIG. 5B).

Next, as illustrated in FIGS. 3 and 5C, an ACF (anisotropic conductive film) 50 is disposed on the plurality of terminals TM (step S13b).

Next, as illustrated in FIGS. 3, 4C, and 5D an electronic circuit board (for example, an IC chip) 60 is disposed on the ACF 50 (step S13c).

Next, as illustrated in FIGS. 3, 4D, and 5E, a thermocompression bonding step of thermocompression-bonding the plurality of terminals TM and the electronic circuit board 60 using the head 90 of the thermocompression bonding tool is performed (step S13d). As a result, the electronic circuit board 60 is mounted in a portion of the prescribed region PA, as illustrated in FIG. 5F.

In the mounting steps (S13a to S13d) of the first embodiment, the base layer 7 containing a resin (for example, PET) is compressed in advance by heat and pressure in the preparation step (blank strike) of step S13a (see FIGS. 5A and 5B). As a result, deformation in the thermocompression bonding step (main strike) of step S13d is suppressed (see FIGS. 5E and 5F). This can reduce the possibility that the wiring or the like in the TFT layer 4 may be damaged or that the electronic circuit board 60 may be mounted incorrectly.

In the EL device 2, as illustrated in FIG. 5G, the portion of the base layer 7 overlapping with the plurality of terminals satisfies at least one of a smaller thickness, a higher modulus of elasticity, a higher hardness, or a higher density than the portion of the base layer 7 overlapping with the light-emitting element layer 5.

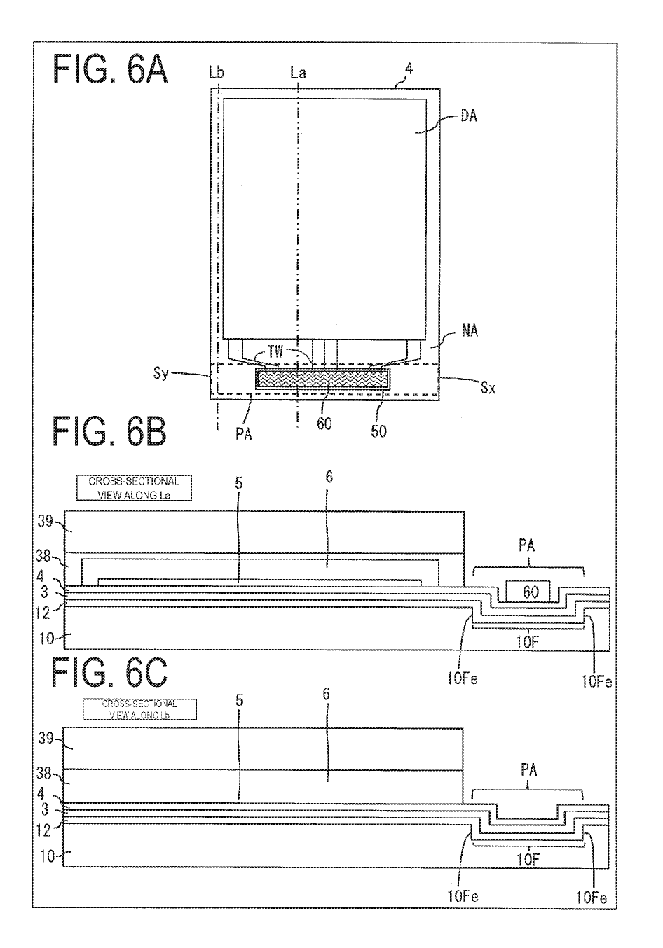

In addition, as illustrated in FIGS. 5G and 6, the base layer 7 includes a deformed portion 10F which satisfies at least one of a smaller thickness, a higher modulus of elasticity, a higher hardness, or a higher density than the portion of the base layer 7 overlapping with the light-emitting element layer 5. In a plan view, the electronic circuit board 60 is positioned within the edge 10Fe of the deformed portion 10F. Note that the deformed portion 10F matches the prescribed region PA subjected to the blank strike in FIG. 5A. In FIGS. 6A to 6C, the thickness of the lower face film 10 of the base layer 7 is described as becoming smaller as an example. The deformed portion 10F may be a region (including the mounting region) extending from one side face Sx of the EL device 2 to the opposing side face Sy.

Note that in the case where the preparation step of step S13a (blank strike) is not performed, the base layer 7 deforms in the thermocompression bonding step (main strike), as illustrated in FIG. 5H. Such deformation leads to a possibility that the wiring or the like in the TFT layer 4 may be damaged or that the electronic circuit board 60 may be mounted incorrectly.

In the first embodiment, the length in the direction along the edge E1 of the TFT layer 4 in the prescribed region PA is equal to the length of the edge E1. In addition, the head width of the thermocompression bonding tool is longer than the width of the edge E1. As a result, the base layer 7 on the lower side of the prescribed region PA can be compressed uniformly by the preparation step of step S13a, and the flatness of the mounting surface (portion of the prescribed region PA) can be secured.

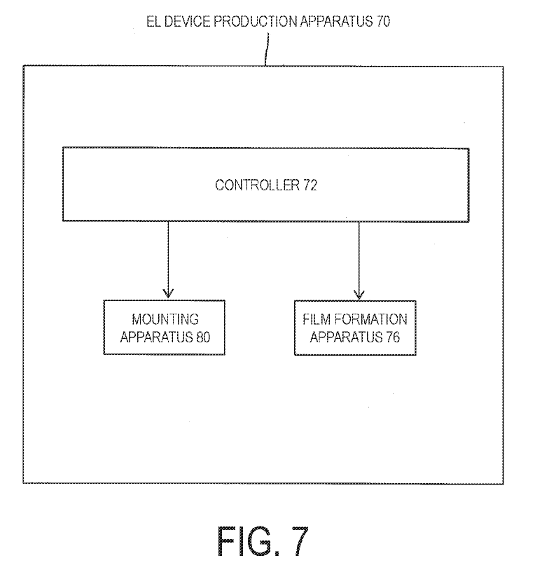

Note that, as illustrated in FIG. 7, an EL device production apparatus 70 includes a mounting apparatus 80 including a thermocompression bonding tool, a film formation apparatus 76, and a controller 72 configured to control the mounting apparatus 80 and the film formation apparatus 76. The mounting apparatus 80 executes steps S13a to S13d of FIG. 3 under the control of the controller 72.

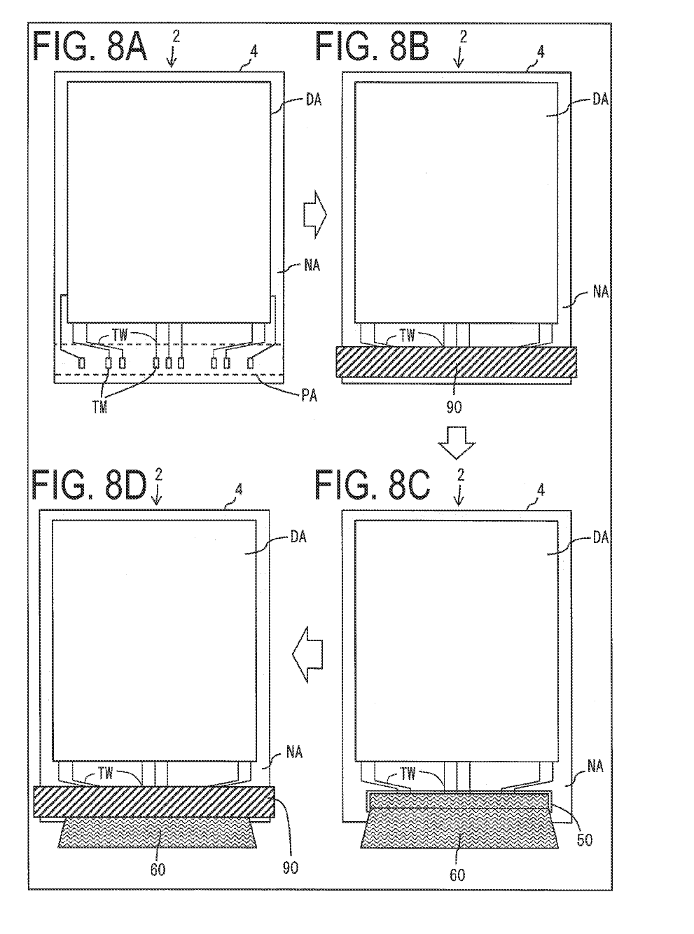

The electronic circuit board 60 of the first embodiment is not limited to an IC chip. For example, when the electronic circuit board 60 is an FPC, the electronic circuit board 60 may be mounted as illustrated in FIGS. 8A to 8D.

### Second Embodiment

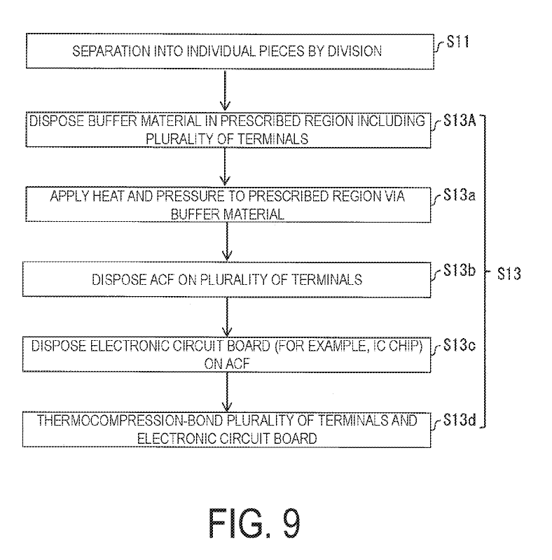

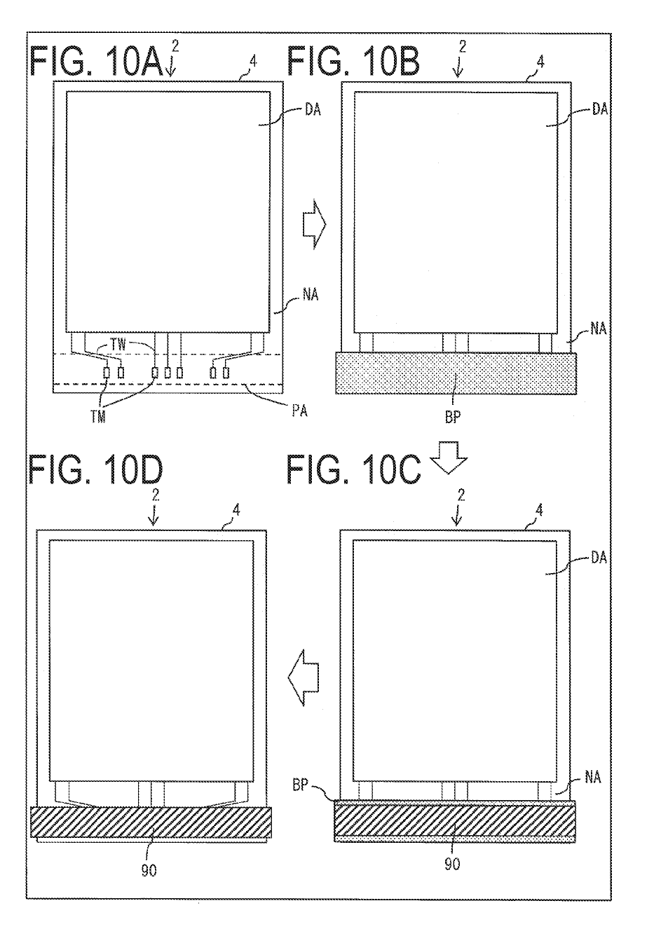

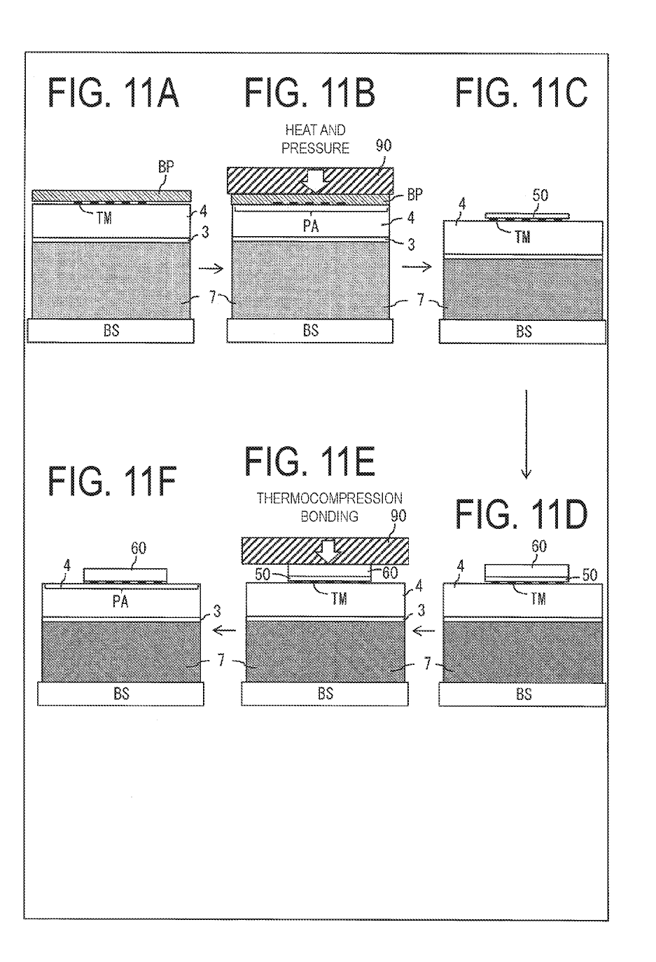

FIG. 9 is a flowchart illustrating the mounting step in a second embodiment. FIGS. 10A to 10D are plan views illustrating the preparation step in the second embodiment. FIGS. 11A to 11F are cross-sectional views illustrating the preparation step in the second embodiment.

First, as illustrated in FIGS. 9, 10A, 10B, and 11A, a buffer material BP is disposed in a prescribed region PA including a plurality of terminals TM (step S13A). Next, as illustrated in FIGS. 9, 10C, and 11B, heat and pressure are applied to the prescribed region PA via the buffer material BP using a head 90 of a thermocompression bonding tool (preparation step, step S13a). When step S13a is complete, the head 90 of the thermocompression bonding tool is separated from the plurality of terminals TM, and the buffer material BP is conveyed.

Next, as illustrated in FIG. 11C, an ACF (anisotropic conductive film) 50 is disposed on the plurality of terminals TM (step S13b). Next, as illustrated in FIG. 11D, an electronic circuit board (for example, an IC chip) 60 is disposed on the ACF 50 (step S13c). Next, as illustrated in FIGS. 10D and 11E, thermocompression bonding is performed between the plurality of terminals TM and the electronic circuit board 60 using the head 90 of the thermocompression bonding tool (step S13d). As a result, the electronic circuit board 60 is mounted in a portion of the prescribed region PA, as illustrated in FIG. 11F.

In the preparation step illustrated in FIGS. 9 to 11, heat and pressure are indirectly applied to the prescribed region PA via the buffer material BP. As a result, the risk that the terminals may deform due to an excessive increase in the temperature of the prescribed region PA can be reduced. In addition, the buffer material BP preferably has a shape which allows the buffer material BP to cover the entire prescribed region PA. As a result, heat and pressure can be applied uniformly to the prescribed region PA. Note that the buffer material BP is preferably made of the same material as the substrate of the electronic circuit board. As a result, the deformation of the base layer 7 in the thermocompression bonding step (step S13d) can be more effectively suppressed.

### Third Embodiment

In the first and second embodiments, the treatment time of the thermocompression bonding tool (amount of time that heat and pressure are applied to the prescribed region PA from the head 90) may also be varied between the preparation step (step 13a) and the thermocompression bonding step (step 13d). For example, the throughput may be increased by making the treatment time in the preparation step shorter than the treatment time in the thermocompression bonding step.

In addition, the preset pressure of the thermocompression bonding tool may also be varied between the preparation step and the thermocompression bonding step. For example, to increase throughput, the preset pressure in the preparation step may be made larger than the preset pressure in the thermocompression bonding step.

In addition, the preset temperature of the thermocompression bonding tool may also be varied between the preparation step and the thermocompression bonding step. For example, to increase throughput, the preset temperature in the preparation step may be made higher than the preset temperature in the thermocompression bonding step.

In addition, the head shape of the thermocompression bonding tool may also be varied between the preparation step and the thermocompression bonding step. For example, heat and pressure may be applied uniformly by making the head used in the preparation step larger than the head used in the thermocompression bonding step. The material of the head may also be varied.

Supplement

The production method for an EL device according to a first aspect is a production method for an EL device including a base layer, a light-emitting element layer, a plurality of terminals, and an electronic circuit board mounted on the plurality of terminals; the production method including: a preparation step of directly or indirectly applying heat and pressure to a prescribed region including the plurality of terminals without any overlap between the plurality of terminals and the electronic circuit board; and a thermocompression bonding step of thermocompression-bonding the plurality of terminals and the electronic circuit board.

In a second aspect, the base layer has flexibility.

In a third aspect, an anisotropic conductive material is disposed between the plurality of terminals and the electronic circuit board after the preparation step and before the thermocompression bonding step.

In a fourth aspect, the EL device includes a TFT layer, and the prescribed region includes a region along one edge of the TFT layer.

In a fifth aspect, heat and pressure are applied to the prescribed region via a buffer material in the preparation step.

In a sixth aspect, the electronic circuit board is mounted in a portion of the prescribed region.

In a seventh aspect, a length along the edge of the prescribed region is equal to a length of the edge.

In an eighth aspect, the TFT layer includes an organic interlayer insulating film, and the plurality of terminals are formed on the organic interlayer insulating film.

In a ninth aspect, the buffer material is made of the same material as a substrate of the electronic circuit board.

In a tenth aspect, the preparation step and the thermocompression bonding step are performed with a thermocompression bonding tool.

In an eleventh aspect, the head area of the thermocompression bonding tool is greater than the area of the prescribed region.

In a twelfth aspect, a treatment time of the thermocompression bonding tool is varied between the preparation step and the thermocompression bonding step.

In a thirteenth aspect, a preset pressure of the thermocompression bonding tool is varied between the preparation step and the thermocompression bonding step.

In a fourteenth aspect, a preset temperature of the thermocompression bonding tool is varied between the preparation step and the thermocompression bonding step.

In a fifteenth aspect, a head shape of the thermocompression bonding tool is varied between the preparation step and the thermocompression bonding step.

In a sixteenth aspect, a resin layer and a lower face film are included in the base layer.

In a seventeenth aspect, the lower face film is made of polyethylene terephthalate.

In an eighteenth aspect, after a resin layer, a barrier layer, a TFT layer, a light-emitting element layer, and a sealing layer are formed on an upper face side of a support, the support is peeled from the resin layer, and the lower face film is adhered to a lower face of the resin layer.

In a nineteenth aspect, the electronic circuit board includes an IC chip or a flexible printed circuit board.

The EL device of a twentieth aspect is an EL device including: a base layer, a light-emitting element layer, a plurality of terminals, and an electronic circuit board mounted on the plurality of terminals; wherein a portion of the base layer overlapping with the plurality of terminals satisfies at least one of a smaller thickness, a higher modulus of elasticity, a higher hardness, or a higher density than a portion of the base layer overlapping with the light-emitting element layer.

In the EL device of a twenty-first aspect, the base layer includes a deformed portion satisfying at least one of a smaller thickness, a higher modulus of elasticity, higher hardness, or a higher density than the portion overlapping with the light-emitting element layer; and the electronic circuit board is positioned within an edge of the deformed portion in a plan view.

In the EL device of a twenty-second aspect, the deformed portion extends from one side face of the EL device to an opposing side face.

The production apparatus for an EL device according to a twenty-third aspect is a production apparatus for an EL device including a base layer, a light-emitting element layer, a plurality of terminals, and an electronic circuit board mounted on the plurality of terminals; wherein the production apparatus for an EL device performs: a preparation step of directly or indirectly applying heat and pressure to a prescribed region including the plurality of terminals without any overlap with the electronic circuit board; and then performs a thermocompression bonding step of thermocompression-bonding the plurality of terminals and the electronic circuit board.

The mounting apparatus of a twenty-fourth aspect is a mounting apparatus used in the production of an EL device including a base layer, a light-emitting element layer, a plurality of terminals, and an electronic circuit board mounted on the plurality of terminals; wherein the mounting apparatus performs: a preparation step of directly or indirectly applying heat and pressure to a prescribed region including the plurality of terminals without any overlap with the electronic circuit board; and then performs a thermocompression bonding step of thermocompression-bonding the plurality of terminals and the electronic circuit board.

The disclosure is not limited to each of the embodiments stated above, and embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

2 EL device
4 TFT layer
5 Light-emitting element layer
6 Sealing layer
7 Base layer
10 Lower face film
12 Resin layer
16 Inorganic insulating film
18 Inorganic insulating film
20 Inorganic insulating film
21 Organic interlayer film
24 EL layer
26 First inorganic sealing film
27 Organic sealing film
28 Second inorganic sealing film
50 Support
60 Electronic circuit board
70 EL device production apparatus
80 Mounting apparatus
90 Head of thermocompression bonding tool
PA Prescribed region
BP Buffer material
TM Terminal

1-17. (canceled)

18. A production method for an EL device including a base layer, a light-emitting element layer, a plurality of terminals, and an electronic circuit board mounted on the plurality of terminals;
the production method comprising:
a preparation step of directly or indirectly applying heat and pressure to a prescribed region including the plurality of terminals without any overlap between the plurality of terminals and the electronic circuit board; and
a thermocompression bonding step of thermocompression-bonding the plurality of terminals and the electronic circuit board,
wherein the base layer has flexibility,
the base layer includes a resin layer and a lower face film, and
after the resin layer, a barrier layer, a TFT layer, the light-emitting element layer, and a sealing layer are formed on an upper face side of a support, the support is peeled from the resin layer, and the lower face film is adhered to a lower face of the resin layer.

19-24. (canceled)

25. The production method for an EL device according to claim 18,
wherein an anisotropic conductive material is disposed between the plurality of terminals and the electronic circuit board after the preparation step and before the thermocompression bonding step.

26. The production method for an EL device according to claim 18,
wherein the EL device includes the TFT layer, and
the prescribed region includes a region along one edge of the TFT layer.

27. The production method for an EL device according to claim 18,
wherein heat and pressure are applied to the prescribed region via a buffer material in the preparation step.

28. The production method for an EL device according to claim 18,
wherein the electronic circuit board is mounted in a portion of the prescribed region.

29. The production method for an EL device according to claim 26,
wherein a length along the edge of the prescribed region is equal to a length of the edge.

30. The production method for an EL device according to claim 26,
wherein the TFT layer includes an organic interlayer insulating film, and
the plurality of terminals are formed on the organic interlayer insulating film.

31. The production method for an EL device according to claim 27,
wherein the buffer material is made of the same material as a substrate of the electronic circuit board.

32. The production method for an EL device according to claim 18,
wherein the preparation step and the thermocompression bonding step are performed with a thermocompression bonding tool.

33. The production method for an EL device according to claim 32,
wherein a head area of the thermocompression bonding tool is greater than an area of the prescribed region.

34. The production method for an EL device according to claim 32,
wherein a treatment time of the thermocompression bonding tool is varied between the preparation step and the thermocompression bonding step.

35. The production method for an EL device according to claim 32,
wherein a preset pressure of the thermocompression bonding tool is varied between the preparation step and the thermocompression bonding step.

36. The production method for an EL device according to claim 32,
wherein a preset temperature of the thermocompression bonding tool is varied between the preparation step and the thermocompression bonding step.

37. The production method for an EL device according to claim 32,
wherein a head shape of the thermocompression bonding tool is varied between the preparation step and the thermocompression bonding step.

38. The production method for an EL device according to claim 18,
wherein the lower face film is made of polyethylene terephthalate.

39. The production method for an EL device according to claim 18,
wherein the electronic circuit board includes an IC chip or a flexible printed circuit board.
